(19) United States
(12) Patent Application Publication
(10) Pub. No.: US 2026/0059922 A1
(43) Pub. Date: Feb. 26, 2026

(54) DISPLAY DEVICE AND MANUFACTURING METHOD THEREOF

(71) Applicant: InnoLux Corporation, Miao-Li County (TW)

(72) Inventors: Chih-Lung LIN, Miao-Li County (TW); Hsiao-Tzu CHANG, Miao-Li County (TW); Wen-Tse LI, Miao-Li County (TW); Yung-Hsun WU, Miao-Li County (TW); Shih-Fu LIAO, Miao-Li County (TW)

(21) Appl. No.: 19/282,261

(22) Filed: Jul. 28, 2025

Related U.S. Application Data
(60) Provisional application No. 63/686,008, filed on Aug. 22, 2024.

(30) Foreign Application Priority Data
Feb. 11, 2025 (CN) 202510149579.6

(51) Int. Cl. H10H 29/855; H01L 25/075; H10H 29/01

(52) U.S. Cl. CPC H10H 29/855; H01L 25/0753; H10H 29/0363

(57) ABSTRACT

A display device includes a circuit substrate, first and second light emitting units disposed on the circuit substrate, and first and second light collection structures. The first light collection structure corresponds to the first light emitting unit, and the second light collection structure corresponds to the second light emitting unit. In a top-view direction, there is a first distance between the first light emitting unit and the first light collection structure, there is a second distance between the second light emitting unit and the second light collection structure, the first light collection structure has a first diameter, and the first distance, the second distance and the first diameter satisfy: |C1−C2|≤⅕×D1, where C1 represents the first distance, C2 represents the second distance, D1 represents the first diameter, and C1 and C2 are each not equal to zero.

### CROSS-REFERENCE TO RELATED APPLICATIONS

This application claims the benefit of filing date of U.S. Provisional Application Ser. No. 63/686,008 filed on Aug. 22, 2024 under 35 USC § 119(e)(1), and also claims the benefit of the Chinese Patent Application Serial Number 202510149579.6, filed on Feb. 11, 2025, the subject matters of which are incorporated herein by reference.

### BACKGROUND

### Field of the Disclosure

The present disclosure relates to a display device and a manufacturing method thereof and, more particularly, to a display device having a light collection structure and a manufacturing method thereof.

### Description of Related Art

Light emitting diode (LED) displays have the advantages of fast response speed, power saving, low power consumption, long service life, and good contrast, and have been regarded as one of the displays with potential in the future development of displays.

However, the large light emission angle of the light emitting diode may result in insufficient brightness and affect the visual effect. If the light intensity is increased by increasing the current, the power consumption will increase. In addition, the high temperature during the manufacturing process may easily damage the light emitting diodes, resulting in a decrease in product yield or an increase in production costs.

Therefore, there is an urgent need to provide a display device and a manufacturing method thereof to alleviate and/or obviate the aforementioned defects.

### SUMMARY

The present disclosure provides a display device, which includes: a circuit substrate; a plurality of light emitting units disposed on the circuit substrate, wherein the light emitting units include a first light emitting unit and a second light emitting unit; and a plurality of light collection structures including a first light collection structure and a second light collection structure, wherein the first light collection structure corresponds to the first light emitting unit, and the second light collection structure corresponds to the second light emitting unit; wherein, in a top-view direction, there is a first distance between a center of the first light emitting unit and a center of the first light collection structure, there is a second distance between a center of the second light emitting unit and a center of the second light collection structure, the first light collection structure has a first diameter, and the first distance, the second distance and the first diameter satisfy: |C1−C2|≤⅕×D1, where C1 represents the first distance, C2 represents the second distance, D1 represents the first diameter, and C1 and C2 are each not equal to zero.

The present disclosure further provides a manufacturing method of a display device, which includes the steps of: providing a lens substrate, wherein the lens substrate includes a substrate and a plurality of light collection structures, and the light collection structures are formed on the substrate; providing a panel, wherein the panel includes a circuit substrate and a plurality of light emitting units, and the light emitting units are disposed on the circuit substrate; and assembling the lens substrate with the panel so that each of the light emitting units corresponds to one of the light collection structures.

Other novel features of the disclosure will become more apparent from the following detailed description when taken in conjunction with the accompanying drawings.

### BRIEF DESCRIPTION OF DRAWINGS

FIG. 1 is a schematic top view of a portion of a display device according to an embodiment of the present disclosure;

FIG. 2 is a schematic cross-sectional view of a portion of a display device according to an embodiment of the present disclosure;

FIG. 3 is a cross-sectional schematic diagram of a portion of a display device according to an embodiment of the present disclosure;

FIG. 4 is a cross-sectional schematic diagram of a portion of a display device according to an embodiment of the present disclosure;

FIG. 5 is a schematic cross-sectional view of a portion of a display device according to an embodiment of the present disclosure;

FIG. 6A to FIG. 6D are schematic diagrams showing the preparation of a display device according to an embodiment of the present disclosure.

FIG. 7 is a schematic top view of a portion of a display device according to an embodiment of the present disclosure;

FIG. 8 is a diagram showing a light pattern of a display device according to an embodiment of the present disclosure;

FIG. 9 is a schematic diagram showing a display device according to an embodiment of the present disclosure being applied to a vehicle display; and

FIG. 10 is a schematic top view of a portion of a display device according to an embodiment of the present disclosure.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in the specification and claims, unless otherwise specified, having “one” element is not limited to having a single said element, but one or more said elements may be provided. In addition, in the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. A “first” element and a “second” element may appear together in the same component, or separately in different components. The existence of an element with a larger ordinal number does not necessarily mean the existence of another element with a smaller ordinal number.

In the entire specification and appended claims of the present disclosure, certain words are used to refer to specific components. Those skilled in the art should understand that electronic device manufacturers may refer to the same components by different names. The present disclosure does not intend to distinguish those components with the same function but different names. In the following description and claims, words such as “comprising”, “including”, and “having” are open type words, so they should be interpreted as meaning “including but not limited to”. Therefore, when the terms “comprising”, “including” and/or “having” are used in the description of the present disclosure, they specify the existence of corresponding features, regions, steps, operations and/or components, but do not exclude the existence of one or more corresponding features, regions, steps, operations and/or components.

In the description, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values in between.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side. When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

Furthermore, in the present disclosure, an optical microscope (OM), a scanning electron microscope (SEM), a thin film thickness profiler (α-step), an ellipsometer, or other suitable methods may be used to measure the thickness, length, width of each component or the distance and angle between components. In detail, according to some embodiments, a scanning electron microscope may be used to obtain a cross-sectional image of a structure and measure the thickness, length, width of each component or the distance and angle between components. In addition, there may be a certain error in any two values or directions used for comparison. If the first value is equal to the second value, it implies that there may be an error of about 10% between the first value and the second value. If the first direction is perpendicular to the second direction, the angle between the first direction and the second direction may be 80 to 100 degrees. If the first direction is parallel to the second direction, the angle between the first direction and the second direction may be 0 to 10 degrees.

The embodiments of the present disclosure may be understood together with the drawings, and the drawings of the present disclosure are also regarded as part of the disclosure description. It should be understood that the drawings of the present disclosure are not in scale and, in fact, the dimensions of elements may be arbitrarily enlarged or reduced in order to clearly illustrate features of the present disclosure.

It should be noted that the technical solutions provided in different embodiments below may be replaced, combined or mixed with each other to constitute another embodiment without violating the spirit of the present disclosure.

The display device disclosed herein may be applied to any electronic device. The electronic device may include, for example, a light emitting device, a display device, a sensing device, an antenna device, a touch device, a tiled device or other suitable electronic devices, but not limited thereto. The display device disclosed herein may include a light emitting diode, a color conversion layer or other suitable materials, or a combination thereof, but not limited thereto. The electronic device may be, for example, a bendable, stretchable, foldable, rollable and/or flexible electronic device, but not limited thereto. The display device may be used, for example, in notebook computers, public displays, tiled displays, vehicle displays, touch displays, transparent displays, double-sided displays, virtual reality displays, augmented reality displays, 3D displays, monochrome displays, color displays, televisions, monitors, smart phones, tablet computers, light source modules, lighting equipment, military equipment, or electronic devices used in the above products, but not limited thereto. The display device may include, for example, liquid crystal molecules, light emitting diodes, a color conversion layer, other suitable display media, or a combination thereof, but not limited thereto. The color conversion layer may include wavelength conversion materials and/or filter materials. The color conversion layer may include, for example, fluorescent materials, phosphor materials, quantum dot (QD) materials, other suitable materials or a combination thereof, but not limited thereto. The display device may include a liquid crystal display device, an electrophoretic display device, or other suitable devices, but not limited thereto. The sensing device may be, for example, a sensing device for detecting capacitance changes, light, heat energy, or ultrasound, but not limited thereto. The sensing device may include, for example, a biometric sensor, a touch sensor, a fingerprint sensor, other suitable sensors, or a combination of the above types of sensors. The antenna device may be, for example, a liquid crystal antenna or other types of antennas, but not limited thereto. The tiled device may include, for example, a tiled display device or a tiled antenna device, but not limited thereto. In addition, the shape of the electronic device may be, for example, rectangular, circular, polygonal, a shape with curved edges, a curved shape, or other suitable shapes. The electronic device may have peripheral systems such as a driving system, a control system, a light source system, a shelf system, etc. It should be noted that the electronic device disclosed in the present disclosure is exemplified by a display device, but the present disclosure is not limited thereto.

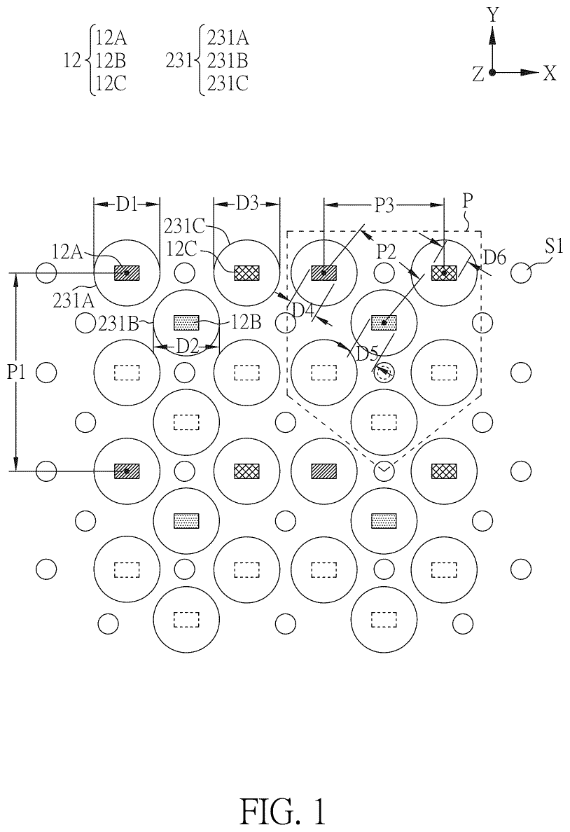

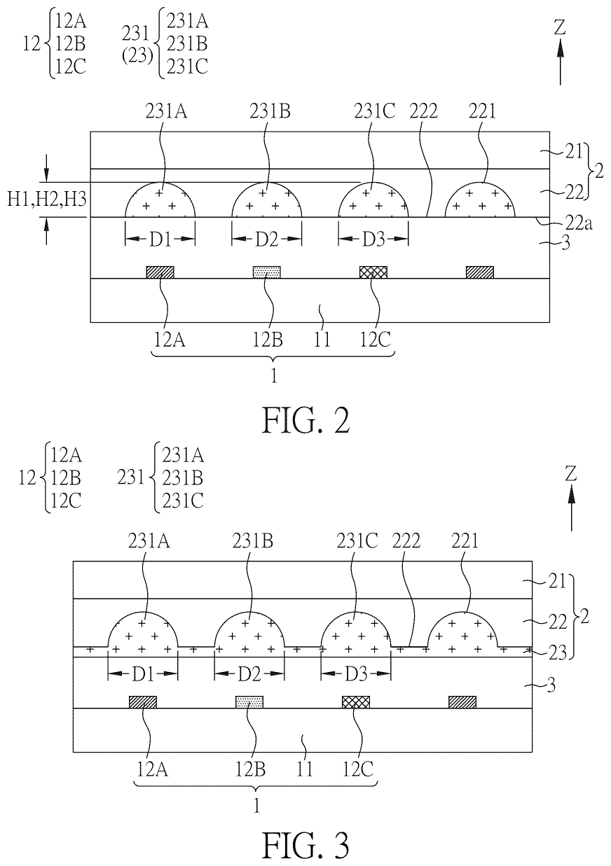

FIG. 1 is a schematic top view of a portion of a display device according to an embodiment of the present disclosure. FIG. 2 is a schematic cross-sectional view of a portion of a display device according to an embodiment of the present disclosure. For the convenience of explanation, FIG. 1 only shows some components. In addition, in the figures, the light emitting units 12 of the same color are represented by the same filling pattern, and the dotted line represents that the light emitting unit 12 is not provided at that location.

In one embodiment of the present disclosure, as shown in FIG. 1 and FIG. 2, the display device may include: a circuit substrate 11; a plurality of light emitting units 12 disposed on the circuit substrate 11, wherein the light emitting units 12 include a first light emitting unit 12A and a second light emitting unit 12B; and a plurality of light collection structures 231 including a first light collection structure 231A and a second light collection structure 231B, wherein the first light collection structure 231A corresponds to the first light emitting unit 12A, and the second light collection structure 231B corresponds to the second light emitting unit 12B. The light collection structure 231 may collect the light of the light emitting unit 12, thereby increasing the light output intensity of the light emitting unit 12.

In the present disclosure, the “first light emitting unit 12A” and the “second light emitting unit 12B” refer to, for example, two light emitting units 12 having different colors. The color of the light emitting unit 12 may be, for example, red, green, blue, white or other suitable colors. In the present disclosure, “a light collection structure 231 corresponds to a light emitting unit 12” means that, for example, in the top-view direction Z, the light collection structure 231 overlaps with the light emitting unit 12, such as, in the top-view direction Z, the first light collection structure 231A overlaps with the first light emitting unit 12A, and the second light collection structure 231B overlaps with the second light emitting unit 12B. In one embodiment of the present disclosure, in the top-view direction Z, the light collection structures 231 do not overlap with each other.

In one embodiment of the present disclosure, as shown in FIG. 1, there is a pixel pitch P1 between adjacent first light emitting units 12A, and there is a first sub-pixel pitch P2 between the first light emitting unit 12A and the second light emitting unit 12B, wherein the pixel pitch P1 may be greater than or equal to the first sub-pixel pitch P2. In the present disclosure, the “pixel pitch P1” or “first sub-pixel pitch P2” refers to, for example, the shortest distance between the center points of two light emitting units 12 in a top view.

In one embodiment of the present disclosure, as shown in FIG. 1 and FIG. 2, the light emitting units 12 may further include a third light emitting unit 12C, and the light collection structures 231 may further include a third light collection structure 231C, wherein the third light collection structure 231C corresponds to the third light emitting unit 12C. In other words, in the top-view direction Z, the third light collection structure 231C overlaps with the third light emitting unit 12C. In the present disclosure, the “third light emitting unit 12C” refers to, for example, a third light emitting unit 12C having a color different from those of the first light emitting unit 12A and the second light emitting unit 12B. In one embodiment of the present disclosure, as shown in FIG. 1, a second sub-pixel pitch P3 is provided between the first light emitting unit 12A and the third light emitting unit 12C, wherein the pixel pitch P1 may be greater than or equal to the second sub-pixel pitch P3. In one embodiment of the present disclosure, as shown in FIG. 1, the second sub-pixel pitch P3 may be greater than or equal to the first sub-pixel pitch P2, but the present disclosure is not limited thereto. The “second sub-pixel pitch P3” refers to, for example, the shortest distance between the center points of two light emitting units 12 in a top view.

In one embodiment of the present disclosure, as shown in FIG. 1, in the top-view direction Z, the center of the first light emitting unit 12A and the center of the first light collection structure 231A may substantially overlap. In other words, the distance between the center of the first light emitting unit 12A and the center of the first light collection structure 231A may be zero. Similarly, in the top-view direction Z, the center of the second light emitting unit 12B and the center of the second light collection structure 231B may substantially overlap. In other words, the distance between the center of the second light emitting unit 12B and the center of the second light collection structure 231B may be zero. In the top-view direction Z, the center of the third light emitting unit 12C and the center of the third light collection structure 231C may substantially overlap. In other words, the distance between the center of the third light emitting unit 12C and the center of the third light collection structure 231C may be zero.

In one embodiment of the present disclosure, as shown in FIG. 1, in the top-view direction Z, the first light collection structure 231A has a first diameter D1, the second light collection structure 231B has a second diameter D2, and the third light collection structure 231C has a third diameter D3, wherein the first diameter D1, the second diameter D2 and the third diameter D3 may be the same or different from each other, and may be adjusted depending on the desired light collection effect. In one embodiment of the present disclosure, as shown in FIG. 2, in the cross-sectional view, the light collection structures 231 may be semicircular and may each have a height, for example, the first light collection structure 231A has a first height H1, the second light collection structure 231B has a second height H2, and the third light collection structure 231C has a third height H3, wherein the first height H1, the second height H2, and the third height H3 may be the same or different from each other and may be adjusted depending on the desired light collection effect. In one embodiment of the present disclosure, the first diameter D1 may be greater than the first height H1, the second diameter D2 may be greater than the second height H2, and/or the third diameter D3 may be greater than the third height H3, but the present disclosure is not limited thereto.

In one embodiment of the present disclosure, as shown in FIG. 1, in the top-view direction Z, the diameter of the light collection structure 231 may be larger than the size of the light emitting unit 12. In more detail, the first diameter D1 of the first light collection structure 231A may be larger than the size D4 of the first light emitting unit 12A, the second diameter D2 of the second light collection structure 231B may be larger than the size D5 of the second light emitting unit 12B, and the third diameter D3 of the third light collection structure 231C may be larger than the size D6 of the third light emitting unit 12C. The “size of the light emitting unit 12” refers to, for example, the size of the diagonal line of the light emitting unit 12 in the top-view direction Z. In some embodiments, the “size of the light emitting unit 12” refers to, for example, the maximum distance between any two points of the light emitting unit 12 in the top-view direction Z, or refers to, for example, the diameter of the light emitting unit 12. In one embodiment of the present disclosure, the first diameter D1 of the first light collection structure 231A may be greater than or equal to twice the size D4 of the first light emitting unit 12A (that is, D1≥2×D4), the second diameter D2 of the second light collection structure 231B may be greater than or equal to twice the size D5 of the second light emitting unit 12B (that is, D2≥2×D5), and/or the third diameter D3 of the third light collection structure 231C may be greater than or equal to twice the size D6 of the third light emitting unit 12C (that is, D3≥2×D6), but the present disclosure is not limited thereto. In one embodiment of the present disclosure, the first diameter D1 of the first light collection structure 231A, the second diameter D2 of the second light collection structure 231B, and the third diameter D3 of the third light collection structure 231C are smaller than or equal to the pixel pitch P1. For example, the first diameter D1 of the first light collection structure 231A, the second diameter D2 of the second light collection structure 231B, and the third diameter D3 of the third light collection structure 231C are smaller than or equal to ½ times of the pixel pitch P1, but it is not limited thereto.

In one embodiment of the present disclosure, as shown in FIG. 2, the display device may further include a first material layer 22, wherein the first material layer 22 includes a plurality of recessed portions 221, and the light collection structure 231 is disposed in the recessed portion 221. In one embodiment of the present disclosure, as shown in FIG. 2, the first material layer 22 further includes a flat portion 222, and the flat portion 222 is adjacent to the recessed portions 221. The “recessed portion 221” refers to, for example, a region where a portion of the surface 22a of the first material layer 22 adjacent to the light emitting unit 12 is recessed in a direction away from the light emitting unit 12, and the region of the surface 22a of the first material layer 22 that is not recessed is the flat portion 222. In the present disclosure, the first material layer 22 has a first refractive index n1, the light collection structure 231 may be formed by a second material layer 23, and the second material layer 23 (for example, the light collection structure 231) has a second refractive index n2, wherein the first refractive index n1 is smaller than the second refractive index n2. In one embodiment of the present disclosure, the difference between the first refractive index n1 and the second refractive index n2 may be between 0.3 and 1 (that is, 0.3≤(n2−n1)≤1), for example, may be between 0.3 and 0.9 (that is, 0.3≤(n2−n1)≤0.9) or between 0.3 and 0.7 (that is, 0.3≤(n2−n1)≤0.7), but the present disclosure is not limited thereto. In one embodiment of the present disclosure, the first refractive index n1 may be between 1.2 and 1.8 (that is, 1.2≤n1≤1.8), and the second refractive index n2 may be between 1.5 and 2.1 (that is, 1.5≤n2≤2.1), but the present disclosure is not limited thereto. In the present disclosure, the materials of the first material layer 22 and the second material layer 23 may each include acrylic, resin, optical adhesive (OCA) or a suitable material, which is a transparent, colorless and/or low-haze material.

In one embodiment of the present disclosure, as shown in FIG. 2, the display device may further include a third material layer 3 disposed on the light emitting unit 12, wherein the third material layer 3 has a third refractive index n3, and the third refractive index n3 is smaller than or equal to the second refractive index n2. In the present disclosure, the third material layer 3 may be a single layer or a multi-layer design. When the third material layer 3 is a multi-layer design, the materials of each layer may be the same or different, which may be adjusted according to the combination with the light emitting unit 12. In the present disclosure, the material of the third material layer 3 may include acrylic, resin, optical adhesive (OCA) or a suitable material, which is a transparent, colorless and/or low-haze material.

In one embodiment of the present disclosure, as shown in FIG. 2, the display device may further include a substrate 21, and the first material layer 22 is disposed between the substrate 21 and the third material layer 3. In the present disclosure, the material of the substrate 21 may include glass, quartz, sapphire, ceramic, plastic, polycarbonate (PC), polyimide (PI), polypropylene (PP), polyethylene terephthalate (PET), polymethylmethacrylate (PMMA), other suitable materials or a combination thereof, but the present disclosure is not limited thereto. In the present disclosure, the substrate 21 and the first material layer 22 are made of different materials, but the present disclosure is not limited thereto. In one embodiment of the present disclosure, the refractive index of the substrate 21 is substantially the same as the first refractive index n1 and smaller than the second refractive index n2. Thus, light loss due to mismatching may be reduced, thereby increasing light output intensity. For example, the refractive index of the substrate 21 may be between 1.2 and 1.8, but it is not limited thereto.

In the present disclosure, although not shown in the figures, the circuit substrate 11 may include wires, electronic components, transistors, other suitable components and/or a combination thereof, but the present disclosure is not limited thereto. The suitable electronic components include active components, passive components or a combination thereof, such as capacitors, resistors, inductors, varactors, variable capacitors, filters, diodes, transistors, sensors, micro-electromechanical system (MEMS) components, liquid crystal chips, etc., but the present disclosure is not limited thereto.

In the present disclosure, the light emitting unit 12 may be a light emitting diode. The light emitting diode may include, for example, an organic light emitting diode (OLED), a sub-millimeter light emitting diode (mini LED), a micro light emitting diode (micro LED), or a quantum dot light emitting diode (quantum dot LED, including QLED, QDLED), but the present disclosure is not limited thereto. In one embodiment of the present disclosure, the light emitting unit 12 is a micro light emitting diode (micro LED).

In the present disclosure, the circuit substrate 11 and the light emitting unit 12 may form a panel 1, and the substrate 21, the first material layer 22 and the light collection structure 231 may form a lens substrate 2. The third material layer 3 may be disposed between the panel 1 and the lens substrate 2.

In one embodiment of the present disclosure, the number of light collection structures 231 may be greater than the number of light emitting units 12. In more detail, as shown in FIG. 1, some of the light collection structures 231 are not disposed corresponding to the light emitting units 12. In other words, in the top-view direction Z, some of the light collection structures 231 do not overlap with the light emitting units 12. Thus, the light collection structures 231 not corresponding to the light emitting units 12 may be used as repair areas. When the adjacent light emitting unit 12 is damaged or defective, a new light emitting unit 12 may be disposed in the repair area to replace the defective or damaged light emitting unit 12, thereby reducing the scrapping cost caused thereby. In one embodiment of the present disclosure, as shown in FIG. 1, a pixel unit P may include three light collection structures 231 (that is, a first light collection structure 231A, a second light collection structure 231B, and a third light collection structure 231C) and three light collection structures 231 serving as repair areas (that is, three light collection structures 231 that do not correspond to the light emitting units 12), but the present disclosure is not limited thereto. In other embodiments of the present disclosure, although not shown in the figures, a pixel unit P may also include three light collection structures 231 and one or two light collection structures 231 serving as repair areas.

FIG. 3 is a cross-sectional schematic diagram of a portion of a display device according to an embodiment of the present disclosure. The display device of FIG. 3 is similar to that of FIG. 2 except for the following differences.

In one embodiment of the present disclosure, as shown in FIG. 3, the first material layer 22 includes a flat portion 222 and a plurality of recessed portions 221, and the flat portion 222 is adjacent to the recessed portions 221, wherein a portion of the second material layer 23 is disposed in the recessed portions 221 to form a plurality of light collection structures 231, and a portion of the second material layer 23 is disposed on the flat portion 222. The second material layer 23 may be used as a flat layer to facilitate subsequent processing.

In this embodiment, the light collection structure 231 refers to, for example, a portion of the second material layer 23 disposed in the recessed portion 221 of the first material layer 22. The diameter of the light collection structure 231 refers to, for example, the maximum dimension of the second material layer 23 disposed in the recessed portion 221 of the first material layer 22 in the cross-sectional view.

In the present disclosure, other features of the display device may be as described above and will not be repeated here.

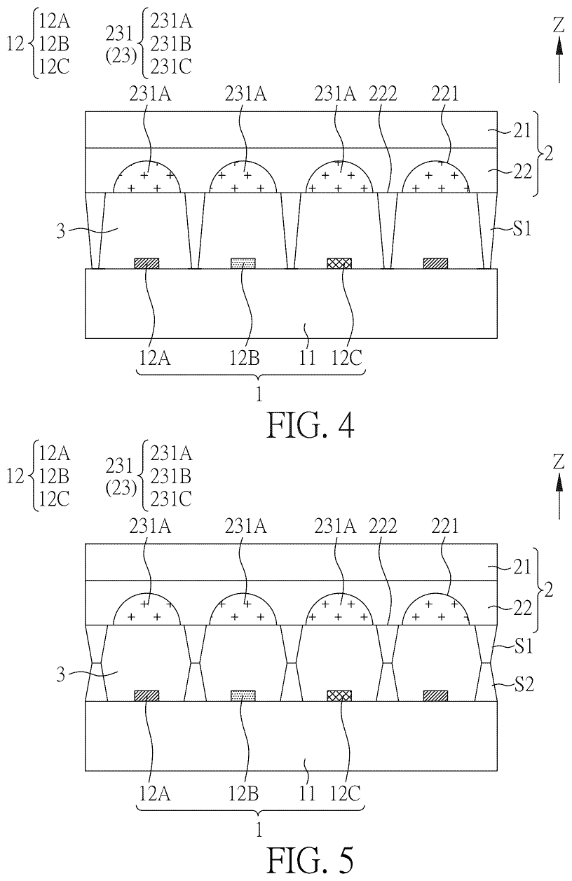

FIG. 4 is a cross-sectional schematic diagram of a portion of a display device according to an embodiment of the present disclosure. The display device of FIG. 4 is similar to that of FIG. 2 except for the following differences.

In one embodiment of the present disclosure, as shown in FIG. 1 and FIG. 4, the display device may further include a spacer S1 formed on the lens substrate 2 or the circuit substrate 1 and disposed between the circuit substrate 1 and the lens substrate 2. The spacer S1 may be disposed corresponding to the flat portion 222 of the first material layer 22. In other words, as shown in FIG. 4, in the top-view direction Z, the spacer S1 overlaps with the flat portion 222 of the first material layer 22. In one embodiment of the present disclosure, as shown in FIG. 1 and FIG. 4, in the top-view direction Z, the spacer S1 and the light collection structure 231 do not overlap. The spacer S1 may be used to fix the distance between the panel 1 and the lens substrate 2, thereby improving the reliability of the display device or improving the light collecting effect of the light collection structure 231.

In the present disclosure, the material of the spacer S1 may include resin, organic material, other suitable materials or a combination thereof, but the present disclosure is not limited thereto. In the present disclosure, the cross-sectional shape of the spacer S1 is not particularly limited, and may be, for example, a cylinder, a rectangular cylinder, a trapezoidal cylinder, a triangular cylinder, a cone, a triangular pyramid, or other irregular cylinders, but the present disclosure is not limited thereto. In the present disclosure, in the top-view direction Z, the shape of the spacer S1 is not particularly limited, and may be, for example, circular, rectangular, trapezoidal, triangular or other irregular shapes, but the present disclosure is not limited thereto.

In one embodiment of the present disclosure, as shown in FIG. 4, the third material layer 3 is arranged between the panel 1 and the lens substrate 2. The third material layer 3 may be a vacuum or filled with air, or may include acrylic, resin, optical adhesive (OCA) or a suitable material, which is a transparent, colorless and/or low-haze material.

In one embodiment of the present disclosure, although not shown in the figures, a portion of the second material layer 23 may be disposed on the flat portion 222 of the first material layer 22, so that, in the top-view direction Z, the spacer S1 may overlap with a portion of the second material layer 23.

In the present disclosure, other features of the display device may be as described above and will not be repeated here.

FIG. 5 is a schematic cross-sectional view of a portion of a display device according to an embodiment of the present disclosure. The display device of FIG. 5 is similar to that of FIG. 2 except for the following differences.

In one embodiment of the present disclosure, as shown in FIG. 5, the display device may also include a spacer S1 and a further spacer S2. The spacer S1 is formed, for example, on the lens substrate 2, the further spacer S2 is formed, for example, on the circuit substrate 11, and the spacer S1 and the further spacer S2 are disposed between the circuit substrate 11 and the lens substrate 2. The spacer S1 may be disposed corresponding to further spacer S2. In other words, as shown in FIG. 5, in the top-view direction Z, the spacer S1 overlaps with the further spacer S2. The spacer S1 and the further spacer S2 may be disposed corresponding to the flat portion 222 of the first material layer 22. In other words, as shown in FIG. 5, in the top-view direction Z, the spacer S1 and the further spacer S2 overlap with the flat portion 222 of the first material layer 22. In one embodiment of the present disclosure, as shown in FIG. 5, in the top-view direction Z, the spacer S1 and the further spacer S2 do not overlap with the light collection structure 231. The spacer S1 and the further spacer S2 may be used to fix the distance between the panel 1 and the lens substrate 2, thereby improving the reliability of the display device or improving the light collecting effect of the light collection structure 231.

In the present disclosure, the materials of the spacer S1 and the further spacer S2 may each include resin, organic material, other suitable materials or a combination thereof, but the present disclosure is not limited thereto. In the present disclosure, the cross-sectional shapes of the spacer S1 and the further spacer S2 are not particularly limited, for example, they may each be a cylinder, a rectangular cylinder, a trapezoidal cylinder, a triangular cylinder, a cone, a triangular pyramid or other irregular cylinders, but the present disclosure is not limited thereto. In the present disclosure, in the top-view direction Z, the shapes of the spacer S1 and the further spacer S2 are not particularly limited, for example, they may each be circular, rectangular, trapezoidal, triangular or other irregular shapes, but the present disclosure is not limited thereto.

In one embodiment of the present disclosure, as shown in FIG. 5, the third material layer 3 is disposed between the panel 1 and the lens substrate 2. The third material layer 3 may be a vacuum or filled with air, or may include acrylic, resin, optical adhesive (OCA) or a suitable material, which is a transparent, colorless and/or low-haze material.

In one embodiment of the present disclosure, although not shown in the figures, a portion of the second material layer 23 may be disposed on the flat portion 222 of the first material layer 22, so that in the top-view direction Z, the spacer S1 and the further spacer S2 may overlap with a portion of the second material layer 23.

In the present disclosure, other features of the display device may be as described above and will not be repeated here.

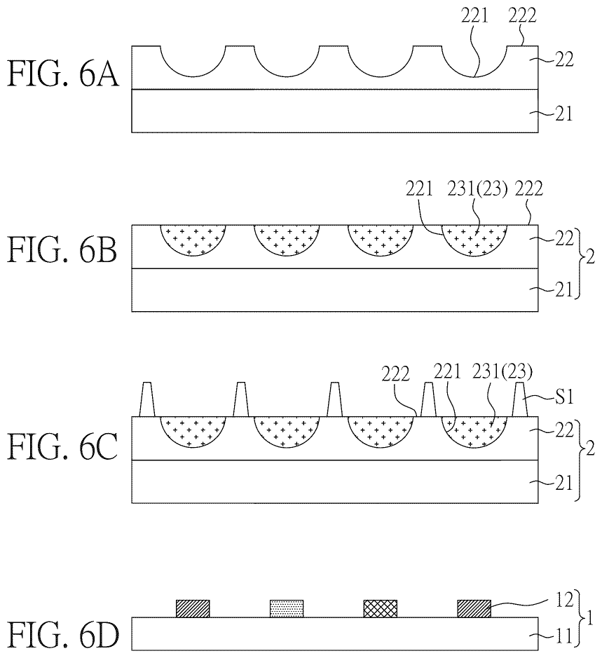

FIG. 6A to FIG. 6D are schematic diagrams showing the preparation of a display device according to an embodiment of the present disclosure.

In one embodiment of the present disclosure, as shown in FIG. 6A to FIG. 6C, a manufacturing method of a display device includes: providing a lens substrate 2, wherein the lens substrate 2 includes a substrate 21 and a plurality of light collection structures 231, and the light collection structures 231 are formed on the substrate 21. In more detail, as shown in FIG. 6A and FIG. 6B, the step of forming the light collection structure 231 on the substrate 21 further includes: forming a first material layer 22 on the substrate 21; patterning the first material layer 22 to form a plurality of recessed portions 221; and forming a second material layer 23 on the first material layer 22, wherein at least a portion of the second material layer 23 is filled into the recessed portions 221 to form the light collection structures 231. Next, as shown in FIG. 6C, a spacer S1 is selectively formed on at least one of the lens substrate 2 or a panel 1 (as shown in FIG. 6D), for example, a spacer S1 is formed on the lens substrate 2, wherein the first material layer 22 includes a flat portion 222, the flat portion 222 is adjacent to the recessed portions 221, and the spacer S1 corresponds to the flat portion 222. In the present disclosure, the method for patterning the first material layer 22 may be, for example, imprint lithography, but the present disclosure is not limited thereto.

In one embodiment of the present disclosure, as shown in FIG. 6D, the manufacturing method of a display device further includes: providing a panel 1, wherein the panel 1 includes a circuit substrate 11 and a plurality of light emitting units 12, and the light emitting units 12 are disposed on the circuit substrate 11; and assembling the lens substrate 2 prepared as above with the panel 1 so that each light emitting unit 12 corresponds to one of the light collection structures 231. In more detail, for example, the lens substrate 2 shown in FIG. 6C is flipped 180° and assembled with the panel 1 shown in FIG. 6D, so that a display device as shown in FIG. 4 may be formed. However, the display device of FIG. 4 is not limited to being manufactured by the above method.

In one embodiment of the present disclosure, before the step of assembling the lens substrate 2 and the panel 1, the method may further include: forming a further spacer S2 on the circuit substrate 11. Afterwards, the lens substrate 2 and the panel 1 are assembled together to form a display device as that shown in FIG. 5. However, the display device of FIG. 5 is not limited to being manufactured by the above method.

In one embodiment of the present disclosure, the spacer S1 may be selectively not formed on the lens substrate 2 and, before the step of assembling the lens substrate 2 and the panel 1, a third material layer 3 is further formed on the panel 1. Afterwards, the lens substrate 2 and the panel 1 are assembled together to form a display device as that shown in FIG. 2. However, the display device of FIG. 2 is not limited to being manufactured by the above method.

In one embodiment of the present disclosure, when forming the second material layer 23 on the first material layer 22, a portion of the second material layer 23 fills the recessed portions 221 to form the light collection structures 231, and a portion of the second material layer 23 may be selectively disposed on the flat portion 222. In this way, the lens substrate 2 and the panel 1 are assembled to form a display device as that shown in FIG. 3. However, the display device of FIG. 3 is not limited to being manufactured by the above method.

In one embodiment of the present disclosure, the light emitting units 12 and the light collection structures 231 are formed on different substrates or base materials respectively, and then the two substrates or base materials are assembled, so that the damage to the light emitting units 12 caused by high temperature in the process may be reduced, thereby improving product yield and/or reducing costs.

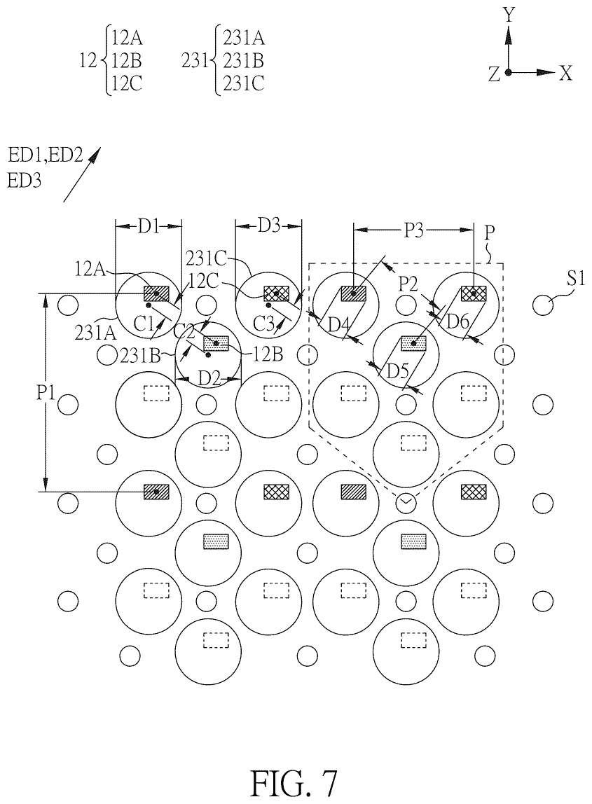

FIG. 7 is a schematic top view of a portion of a display device according to an embodiment of the present disclosure. The display device of FIG. 7 is similar to that of FIG. 1 except for the following differences. For the convenience of explanation, FIG. 7 only shows some components. In addition, in the figure, the light emitting units 12 of the same color are represented by the same filling pattern, and the dotted line represents that the light emitting unit 12 is not provided at that location.

In one embodiment of the present disclosure, as shown in FIG. 7, in the top-view direction Z, the center of the light emitting unit 12 and the center of the light collection structure 231 may not overlap. More specifically, there is a first distance C1 between the center of the first light emitting unit 12A and the center of the first light collection structure 231A, and there is a second distance C2 between the center of the second light emitting unit 12B and the center of the second light collection structure 231B, wherein the first distance C1, the second distance C2, and the first diameter D1 of the first light collection structure 231A may satisfy the following formula:

|C1−C2|≤⅕×D1,

where C1 is the first distance, C2 is the second distance, D1 is the first diameter, and C1 and C2 are each not equal to zero.

In one embodiment of the present disclosure, the first distance C1 may be smaller than or equal to ½ times the difference between the first diameter D1 and the size D4 of the first light emitting unit 12A, that is, the first distance C1 may be smaller than or equal to ½×(the difference between the first diameter D1 and the size D4 of the first light emitting unit 12A) (C1≤½×(D1−D4)). Similarly, the second distance C2 may be smaller than or equal to ½ times the difference between the second diameter D2 and the size D5 of the second light emitting unit 12B, that is, the second distance C2 may be smaller than or equal to ½×(the difference between the second diameter D2 and the size D5 of the second light emitting unit 12B) (C2≤½×(D2−D5)). In one embodiment of the present disclosure, the difference between the first distance C1 and the second distance C2 may be smaller than or equal to 15 μm (that is, |C1−C2|≤15 μm), such as smaller than or equal to 10 μm (i.e., |C1−C2|≤10 μm), smaller than or equal to 5 μm (that is, |C1−C2|≤5 μm), or smaller than or equal to 3 μm (that is, |C1−C2|≤3 μm), but the present disclosure is not limited thereto. In one embodiment of the present disclosure, the first distance C1 and the second distance C2 may each be between 3 μm and 25 μm (that is, 3 μm≤C1≤25 μm, 3 μm≤C2≤25 μm), such as between 3 μm and 20 μm (that is, 3 μm≤C1≤20 μm, 3 μm≤C2≤20 μm) or between 5 μm and 15 μm (that is, 5 μm≤C1≤15 μm, 5 μm≤C2≤15 μm), but the present disclosure is not limited thereto. In one embodiment of the present disclosure, the first distance C1 and the second distance C2 may be viewed as vectors, and the first diameter D1 may be viewed as a scalar. Therefore, the light output angle of the display device may be adjusted by controlling the first distance C1 and/or the second distance C2. When the first distance C1, the second distance C2 and the first diameter D1 satisfy the above formula, the chromatic aberration of the display device may be reduced.

Similarly, in the top-view direction Z, there is a third distance C3 between the center of the third light emitting unit 12C and the center of the third light collection structure 231C, wherein the first distance C1, the third distance C3, and the first diameter D1 of the first light collection structure 231A may satisfy the following formula:

|C1−C3|≤⅕×D1,

where C1 is the first distance, C3 is the third distance, D1 is the first diameter, and C1 and C3 are each not equal to zero.

In one embodiment of the present disclosure, the third distance C3 may be smaller than or equal to ½ times the difference between the third diameter D3 and the size D6 of the third light emitting unit 12C, that is, the third distance C3 may be smaller than or equal to ½×(the difference between the third diameter D3 and the size D6 of the third light emitting unit 12C) (C3≤½×(D3−D6)). The difference between the first distance C1 and the third distance C3 may be smaller than or equal to 15 μm (that is, |C1−C3|15 μm), such as smaller than or equal to 10 μm (that is, |C1−C3|≤10 μm), smaller than or equal to 5 μm (that is, |C1−C3|≤5 μm), or smaller than or equal to 3 μm (that is, |C1−C3|≤3 μm), but the present disclosure is not limited thereto. In one embodiment of the present disclosure, the third distance C3 may be between 3 μm and 25 μm (that is, 3 μm≤C3≤25 μm), such as between 3 μm and 20 μm (that is, 3 μm≤C3≤20 μm) or between 5 μm and 15 μm (that is, 5 μm≤C3≤15 μm), but the present disclosure is not limited thereto. In one embodiment of the present disclosure, the first distance C1 and the third distance C3 may be viewed as vectors, and the first diameter D1 may be viewed as a scalar. Therefore, the light output angle of the display device may be adjusted by controlling the first distance C1 and/or the third distance C3. When the first distance C1, the third distance C3 and the first diameter D1 satisfy the above formula, the chromatic aberration of the display device may be reduced.

In one embodiment of the present disclosure, as shown in FIG. 7, the center of the first light emitting unit 12A and the center of the second light emitting unit 12B deviate from the center of the first light collection structure 231A and the center of the second light collection structure 231B in substantially the same direction, but the present disclosure is not limited thereto. In one embodiment of the present disclosure, as shown in FIG. 7, the first distance C1 extends along a first extension direction ED1, and the second distance C2 extends along a second extension direction ED2, wherein the angle θ between the first extension direction ED1 and the second extension direction ED2 may be between 0° and 20° (that is, 0°≤θ≤20°), such as between 0° and 10° (that is, 0°≤θ≤10°), but the present disclosure is not limited thereto. In one embodiment of the present disclosure, as shown in FIG. 7, the first extension direction ED1 may be substantially parallel to the second extension direction ED2, that is, the angle θ between the first extension direction ED1 and the second extension direction ED2 may be 0°, but the present disclosure is not limited thereto. In one embodiment of the present disclosure, the first distance C1, the second distance C2, and the first diameter D1 are all scalars. Therefore, the light output angle of the display device may be adjusted by controlling the first distance C1 and the first extension direction ED1 and/or the second distance C2 and the second extension direction ED2. When the angle θ between the first extension direction ED1 and the second extension direction ED2 satisfies the above restrictions, and the first distance C1, the second distance C2 and the first diameter D1 satisfy the above formula, the chromatic aberration of the display device may be reduced.

Similarly, as shown in FIG. 7, the center of the first light emitting unit 12A and the center of the third light emitting unit 12C deviate from the center of the first light collection structure 231A and the center of the third light collection structure 231C in substantially the same direction, but the present disclosure is not limited thereto. As shown in FIG. 7, the third distance C3 extends along a third extension direction ED3, wherein an angle θ between the first extension direction ED1 and the third extension direction ED3 may be between 0° and 20° (that is, 0°≤θ≤20°), such as between 0° and 10° (that is, 0°≤θ≤10°), but the present disclosure is not limited thereto. In one embodiment of the present disclosure, as shown in FIG. 7, the first extension direction ED1 may be substantially parallel to the third extension direction ED3, that is, the angle θ between the first extension direction ED1 and the third extension direction ED3 may be 0°, but the present disclosure is not limited thereto. In one embodiment of the present disclosure, the first distance C1, the third distance C3 and the first diameter D1 may all be viewed as scalars. Therefore, the light output angle of the display device may be adjusted by controlling the first distance C1 and the first extension direction ED1 and/or the third distance C3 and the third extension direction ED3. When the angle θ between the first extension direction ED1 and the third extension direction ED3 satisfies the above restrictions, and the first distance C1, the third distance C3 and the first diameter D1 satisfy the above formula, the chromatic aberration of the display device may be reduced.

In one embodiment of the present disclosure, when the angle θ between the first extension direction ED1 and the second extension direction ED2 is between 0° and 20°, and the first distance C1, the second distance C2, and the first diameter D1 of the first light collection structure 231A satisfy the above formula, the light emission result of the display device may be as shown in FIG. 8. From the result, it can be found that the light emission angle θ1 of the display device may be between 0° and 45° (that is, 0°≤θ1≤45°), and when the light emission angle θ1 is between 0° and 30° (that is, 0°≤θ1≤30°), there will be a greater light intensity. The “light output angle θ1” refers to, for example, the angle between the normal line of the display device and the direction in which the strongest light is emitted.

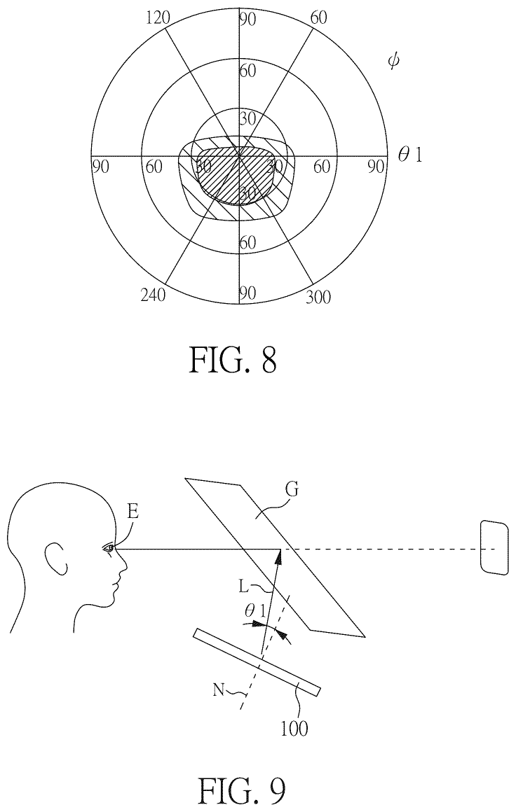

In one embodiment of the present disclosure, when the display device of the present disclosure is applied to a vehicle display, as shown in FIG. 9, the light output angle θ1 of the display device 100 may be adjusted by controlling the first distance C1 and the first extension direction ED1 and/or the second distance C2 and the second extension direction ED2, so that the image of the display device 100 may be projected onto the windshield G parallel to the line of sight of the human eyes E. In more detail, when the angle θ1 between the normal N of the display device 100 and the direction L of the strongest light emission is between 0° and 45° (that is, 0°≤θ1≤45°), the image of the display device 100 may be parallel to the line of sight of the human eyes E when projected onto the windshield G, and may have better light intensity. In the present disclosure, the placement direction of the display device 100 shown in FIG. 9 and the relative position of the human eyes E are only for illustration, that is, the placement direction of the display device 100 may, for example, form an obtuse angle with the line of sight of the human eyes E. At this moment, when viewed from a side view, as shown in FIG. 9, the display device 100 is placed in a direction from the upper left to the lower right, but the present disclosure is not limited thereto. In other aspects of the present disclosure, the placement direction of the display device 100 may, for example, be parallel to the line of sight of the human eyes E, so that, when viewed from a side view, the display device 100 may be placed in parallel, or the placement direction of the display device 100 may, for example, form an acute angle with the line of sight of the human eyes E, so that, when viewed from a side view, the display device 100 may be placed in a direction from the lower left to the upper right.

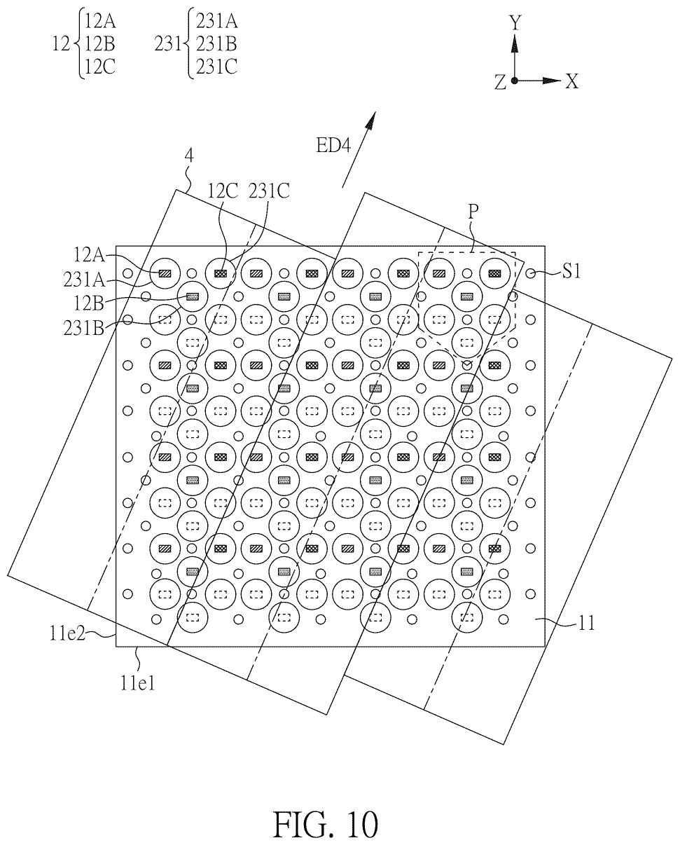

FIG. 10 is a schematic top view of a portion of a display device according to an embodiment of the present disclosure. The display device of FIG. 10 is similar to that of FIG. 1, except for the following differences. In addition, FIG. 10 only shows some components for convenience of explanation.

In one embodiment of the present disclosure, as shown in FIG. 10, the display device may further include a light angle controller 4 disposed on the lens substrate 2 (as shown in FIG. 2), wherein the lens substrate 2 is disposed between the panel 1 (as shown in FIG. 2) and the light angle controller 4. In the present disclosure, the light angle controller 4 includes, for example, a plurality of lenticular lens structures. The light angle controller 4 may be used to adjust the light output angle of the light emitting unit 12 so that the display device may be applied to three-dimensional image display. In one embodiment of the present disclosure, the cross-sectional shape of the lenticular lens is semicircular, but it is not limited thereto. In the present disclosure, as shown in FIG. 10, the size of the lenticular lens structure in the light angle controller 4 is represented by a solid line, and the connection line of the top of the protrusion in the lenticular lens structure is represented by a dot-dashed line, wherein the size of the lenticular lens structure is not particularly limited and may be adjusted as needed.

In one embodiment of the present disclosure, as shown in FIG. 10, the circuit substrate 11 has a first edge 11e1 and a second edge 11e2 connected to each other, the first edge 11e1 extends along a first direction X, and the second edge 11e2 extends along a second direction Y, wherein the first direction X is different from the second direction Y, for example, the first direction X is perpendicular to the second direction Y. As shown in FIG. 10, the extension direction ED4 of the cylindrical lens structure in the light angle controller 4 is not parallel to the first direction X and the second direction Y. Thus, the effect of the light angle controller 4 in displaying a three-dimensional image may be improved.

In one embodiment of the present disclosure, as shown in FIG. 10, in the top-down direction Z, each lenticular lens structure in the light angle controller 4 may partially overlap with at least four pixels P. In more detail, in the first direction X, a lenticular lens structure may partially overlap with at least two pixels P, and in the second direction Y, the lenticular lens structure may partially overlap with at least two pixels P. In this way, the effect of the light angle controller 4 in displaying a three-dimensional image may be improved.

The light angle controller 4 in FIG. 10 is based on three lenticular lens structures as an example, but in other embodiments of the present disclosure, the light angle controller 4 of the display device may include at least two lenticular lens structures, such as four, five or more lenticular lens structures, but the present disclosure is not limited thereto. In addition, in FIG. 10, the light emitting unit 12 and the light collection structure 231 of FIG. 1 are taken as an example, that is, the center of the light emitting unit 12 substantially overlaps with the center of the light collection structure 231, but in other embodiments of the present disclosure, the light emitting unit 12 and the light collection structure 231 may also be those as shown in FIG. 7, that is, there may be a distance between the center of the light emitting unit 12 and the center of the light collection structure 231.

In the present disclosure, by designing the light collection structure 231 to correspond to the light emitting unit 12 and making the specifications of the light collection structure 231 and the light emitting unit 12 satisfy specific restrictions, the light emission angle of the display device may be controlled or the brightness of the display device may be increased. In addition, when the display device is manufactured using the method disclosed herein, the damage to the light emitting unit 12 caused by high temperature during the manufacturing process may be reduced, thereby improving product yield and/or reducing costs.

The aforementioned specific embodiments should be interpreted as merely illustrative, and not limiting the rest of the present disclosure in any way, and the features of different embodiments may be mixed and matched as long as they do not conflict with each other.

1. A display device, comprising:
a circuit substrate;
a plurality of light emitting units disposed on the circuit substrate, wherein the light emitting units include a first light emitting unit and a second light emitting unit; and
a plurality of light collection structures including a first light collection structure and a second light collection structure, wherein the first light collection structure corresponds to the first light emitting unit, and the second light collection structure corresponds to the second light emitting unit;
wherein, in a top-view direction, there is a first distance between a center of the first light emitting unit and a center of the first light collection structure, there is a second distance between a center of the second light emitting unit and a center of the second light collection structure, the first light collection structure has a first diameter, and the first distance, the second distance and the first diameter satisfy:

|C1−C2|≤⅕×D1,
where C1 represents the first distance, C2 represents the second distance, D1 represents the first diameter, and C1 and C2 are each not equal to zero.

2. The display device as claimed in claim 1, wherein the first distance is smaller than or equal to ½ times a difference between the first diameter and a size of the first light emitting unit.

3. The display device as claimed in claim 1, wherein the second light collection structure has a second diameter, and the second distance is smaller than or equal to ½ times a difference between the second diameter and a size of the second light emitting unit.

4. The display device as claimed in claim 1, wherein the first distance extends along a first extension direction, the second distance extends along a second extension direction, and an angle between the first extension direction and the second extension direction is between 0° and 20°.

5. The display device as claimed in claim 1, further comprising a first material layer including a plurality of recessed portions, wherein the light collection structures are disposed in the recessed portions.

6. The display device as claimed in claim 5, wherein the first material layer has a first refractive index, the light collection structure has a second refractive index, and the first refractive index is smaller than the second refractive index.

7. The display device as claimed in claim 6, wherein a difference between the first refractive index and the second refractive index is between 0.3 and 1.

8. The display device as claimed in claim 6, further comprising a third material layer disposed on the light emitting units, wherein the third material layer has a third refractive index, and the third refractive index is smaller than or equal to the second refractive index.

9. The display device as claimed in claim 1, wherein a number of the light collection structures is greater than a number of the light emitting units.

10. The display device as claimed in claim 1, wherein the first diameter is greater than or equal to twice a size of the first light emitting unit, the second light collection structure has a second diameter, and the second diameter is greater than or equal to twice a size of the second light emitting unit.

11. The display device as claimed in claim 10, wherein there is a pixel pitch between adjacent first light emitting units, and the first diameter and the second diameter are each smaller than or equal to ½ times the pixel pitch.

12. The display device as claimed in claim 8, further comprising a substrate, wherein the first material layer is disposed between the substrate and the third material layer, a refractive index of the substrate is equal to the first refractive index and smaller than the second refractive index.

13. The display device as claimed in claim 1, further comprising a first material layer and a second material layer, wherein the first material layer includes a flat portion and a plurality of recessed portions, the flat portion is adjacent to the recessed portions, a portion of the second material layer is disposed in the recessed portions to form the plurality of light collection structures, and a portion of the second material layer is disposed on the flat portion.

14. The display device as claimed in claim 5, further comprising a spacer formed on the circuit substrate, wherein the first material layer further includes a flat portion adjacent to the recessed portions, and the spacer is disposed corresponding to the flat portion.

15. A manufacturing method of a display device, comprising the steps of:
providing a lens substrate, wherein the lens substrate includes a substrate and a plurality of light collection structures, and the light collection structures are formed on the substrate;
providing a panel, wherein the panel includes a circuit substrate and a plurality of light emitting units, and the light emitting units are disposed on the circuit substrate; and
assembling the lens substrate with the panel so that each of the light emitting units corresponds to one of the light collection structures.

16. The manufacturing method as claimed in claim 15, wherein, in the step of providing a lens substrate, the light collection structures being formed on the substrate includes:
forming a first material layer on the substrate;
patterning the first material layer to form a plurality of recessed portions; and
forming a second material layer on the first material layer, wherein at least a portion of the second material layer is filled into the recessed portions to form the light collection structures.

17. The manufacturing method as claimed in claim 16, wherein the first material layer includes a flat portion adjacent to the recessed portions, and a portion of the second material layer is disposed on the flat portion.

18. The manufacturing method as claimed in claim 16, further comprising, before the step of assembling the lens substrate with the panel, the step of forming a spacer on at least one of the lens substrate and the panel, wherein the first material layer includes a flat portion adjacent to the recessed portions, and the spacer corresponds to the flat portion.

19. The manufacturing method as claimed in claim 15, wherein a number of the light collection structures is greater than a number of the light emitting units.

20. The manufacturing method as claimed in claim 15, wherein the light emitting units include a first light emitting unit and a second light emitting unit, the light collection structures include a first light collection structure and a second light collection structure, the first light collection structure corresponds to the first light emitting unit, and the second light collection structure corresponds to the second light emitting unit, wherein, in a top view direction, there is a first distance between a center of the first light emitting unit and a center of the first light collection structure, there is a second distance between a center of the second light emitting unit and a center of the second light collection structure, the first light collection structure has a first diameter, and the first distance, the second distance and the first diameter satisfy:

|C1−C2|≤⅕×D1,
where C1 represents the first distance, C2 represents the second distance, D1 represents the first diameter, and C1 and C2 are each not equal to zero.
